(19) United States
(12) Patent Application Publication
(10) Pub. No.: US 2014/0295612 A1
(43) Pub. Date: Oct. 2, 2014

(54) SOLAR CELL AND MANUFACTURING METHOD THEREOF

(71) Applicant: Au Optronics Corporation, Hsinchu (TW)

(72) Inventors: Cheng-Chang Kuo, Taichung City (TW); Yen-Cheng Hu, New Taipei City (TW); Hsin-Feng Lee, Tainan City (TW); Tsung-Pao Chen, Taichung City (TW); Jen-Chieh Chen, Miaoli County (TW); Zhen-Cheng Wu, Taichung City (TW)

(21) Appl. No.: 14/303,616

(22) Filed: Jun. 13, 2014

Related U.S. Application Data
(62) Division of application No. 13/038,388, filed on Mar. 2, 2011.

(30) Foreign Application Priority Data
Dec. 2, 2010 (TW) 99141947

(51) Int. Cl. H01L 31/18; H01L 31/0224; H01L 31/0236

(52) U.S. Cl. CPC H01L 31/1864; H01L 31/1868; H01L 31/02363; H01L 31/022441
USPC 438/71; 438/98; 438/72

(57) ABSTRACT

A solar cell and a manufacturing method thereof are provided. A laser doping process is adopted to form positive and negative doping regions for an accurate control of the doping regions. No metal contact coverage issue arises since a contact opening is formed by later firing process. The solar cell is provided with a comb-like first electrode, a sheet-like second electrode corresponding to the doping regions to obtain high photoelectric conversion efficiency by fully utilizing the space in the semiconductor substrate. Furthermore, the sheet-like second electrode can be formed by a material having high reflectivity to improve the light utilization rate of the solar cell. The manufacturing process of the solar cell is simplified and the processing yield is improved.

### CROSS-REFERENCE TO RELATED APPLICATION

This application is a Divisional application of and claims the priority benefit of U.S. application Ser. No. 13/038,388, filed on Mar. 2, 2011, now pending, which claims the priority benefit of Taiwan application serial no. 99141947, filed on Dec. 2, 2010. The entirety of each of the above-mentioned patent application is hereby incorporated by reference herein and made a part of this specification.

### BACKGROUND OF THE INVENTION

1. Field of the Invention

The invention relates generally to a solar cell and a manufacturing method thereof, and particularly to a back contacted solar cell and a manufacturing method thereof.

2. Description of Related Art

Solar energy is a clean renewable energy which causes no pollution. To counter the pollution and supply problems of fossil fuels, solar energy has always garnered the most attention. Since solar cells can directly convert solar energy into electrical energy, they have become a rather important research topic nowadays.

A silicon solar cell is a typical solar cell adopted commercially. A principle behind the silicon solar cell is to attach p and n-type semiconductors with each other to form a p-n interface. When sunlight illuminates this p-n structured semiconductor, the energy provided by photons of the sunlight can generate electron-hole pairs in the semiconductors. The electrons and holes are affected by an internal electrical potential, such that holes move towards an electric field direction and electrons move towards an opposite direction. If conductive lines are used to connect the solar cell with a load, a loop may be formed such that an electrical current flows by the load. The solar cell can generate electricity according the above described principle.

Currently available silicon back contacted solar cells form p and n-type doping regions in a silicon substrate by adopting doped films and performing a thermal diffusion process. However, repeated thermal diffusion processes lowers the manufacturing production easily, and an extra screen printing process is required to define the doping regions. Moreover, the manufacturing steps of a conventional silicon back contacted solar cell are complicated and expensive. In addition, when fabricating the metal contacts, the manufacturing yield is easily impacted and lowered by the poor step coverage of the materials.

### SUMMARY OF THE INVENTION

Accordingly, the invention is directed to a solar cell and a manufacturing method thereof, in which the manufacturing process is simplified and the processing yield is improved.

To specifically describe the invention, a manufacturing method of a solar cell including the following steps is provided. A semiconductor substrate having a first surface and a second surface opposite to the first surface is provided. A first passivation layer is formed on the first surface of the semiconductor substrate. A first laser doping process is performed to form a plurality of first openings in the first passivation layer, and forming a plurality of first doping regions in the semiconductor substrate corresponding to the first openings. A first electrode is formed on a portion of the first passivation layer. The first electrode has a comb-like shape with a plurality of branches parallel to each other. The first electrode fills the first openings so as to connect to the first doping regions. A second laser doping process is performed to form a plurality of second openings in the first passivation layer, and forming a plurality of second doping regions in the semiconductor substrate corresponding to the second openings. A second passivation layer and a second electrode are formed in sequence on the first passivation layer. The second passivation layer covers the first electrode and has a plurality of third openings corresponding to the second doping regions. The second electrode has a sheet-like shape and covers the branches of the first electrode. The second electrode fills the third openings so as to connect to the second doping regions.

According to an embodiment of the invention, the first laser doping process includes forming a first doping material layer on the first passivation layer, in which the first doping material layer has a first dopant therein. A laser beam is provided on the first doping material layer and the first passivation layer, to aim the first openings and diffusing the first dopant in the first doping material layer into the semiconductor substrate, so as to form the first doping regions. In addition, the first doping material layer is removed.

According to an embodiment of the invention, the second laser doping process includes forming a second doping material layer on the first passivation layer, in which the second doping material layer has a second dopant therein. A laser beam is provided on the second doping material layer and the first passivation layer, to form the second openings and diffusing the second dopant in the second doping material layer into the semiconductor substrate, so as to form the second doping regions. In addition, the second doping material layer is removed.

According to an embodiment of the invention, a method of forming the first electrode includes a screen printing process.

According to an embodiment of the invention, the manufacturing method of the solar cell further includes performing an annealing process after forming the first electrode.

According to an embodiment of the invention, the manufacturing method of the solar cell further includes performing a texturing process on the second surface of the semiconductor substrate.

According to an embodiment of the invention, the manufacturing method of the solar cell further includes forming an anti-reflection coating layer on the second surface of the semiconductor substrate.

A solar cell is provided, including a semiconductor substrate, a first passivation layer, a first electrode, a second passivation layer, and a second electrode. The semiconductor substrate has a first surface and a second surface opposite to the first surface. The semiconductor substrate has a plurality of first doping regions and a plurality of second doping regions in the first surface. The first passivation layer is formed on the first surface of the semiconductor substrate. The first passivation layer has a plurality of first openings and a plurality of second openings. The first openings correspond to the first doping regions, whereas the second openings correspond to the second doping regions. The first electrode is disposed on the first passivation layer. The first electrode fills the first openings so as to connect to the first doping regions. The first electrode has a comb-like shape with a plurality of branches parallel to each other. The second passivation layer is disposed on the first passivation layer. The second passivation layer covers the first electrode and has a plurality of third openings. The third openings correspond to the second doping regions. The second electrode covers the second passivation layer. The second electrode fills the third openings so as to connect to the second doping regions. The second electrode has a sheet-like shape and covers the branches of the first electrode.

According to an embodiment of the invention, the second surface of the semiconductor substrate is a texturized surface.

According to an embodiment of the invention, the solar cell further includes an anti-reflection coating layer disposed on the second surface of the semiconductor substrate.

According to an embodiment of the invention, the semiconductor substrate includes a negative type lightly doped semiconductor substrate.

According to an embodiment of the invention, the first doping regions include a negative type heavily doped region.

According to an embodiment of the invention, the second doping regions include a positive type heavily doped region.

According to an embodiment of the invention, the first openings include a plurality of grooves.

According to an embodiment of the invention, the second openings and the third openings include a plurality of grooves.

According to an embodiment of the invention, a material of the first electrode includes silver.

According to an embodiment of the invention, a material of the second electrode includes aluminum.

In summary, according to an embodiment of the invention, since laser doping processes are adopted to form doping regions of the solar cell, the location of the doping regions can be accurately defined. Moreover, contact materials may be directly filled in the laser formed openings, and therefore no step coverage issue arises as in conventional metal contacts. In other words, according to embodiments of the invention, the manufacturing process of the solar cell is simplified and the processing yield is improved.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural view of a solar cell according to an embodiment of the invention.

FIG. 2 is a schematic top view of the solar cell depicted in FIG. 1.

FIGS. 3A-3L illustrate the steps of a manufacturing method of a solar cell according to an embodiment of the invention.

FIG. 4 is a schematic top view of a solar cell according to another embodiment of the invention.

### DESCRIPTION OF EMBODIMENTS

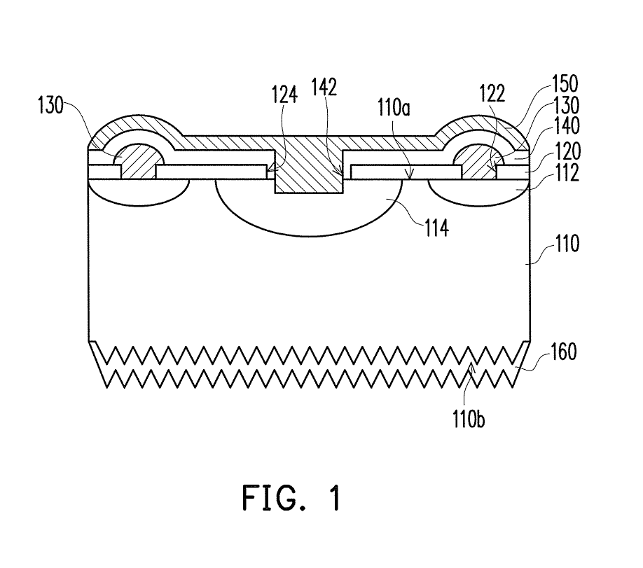

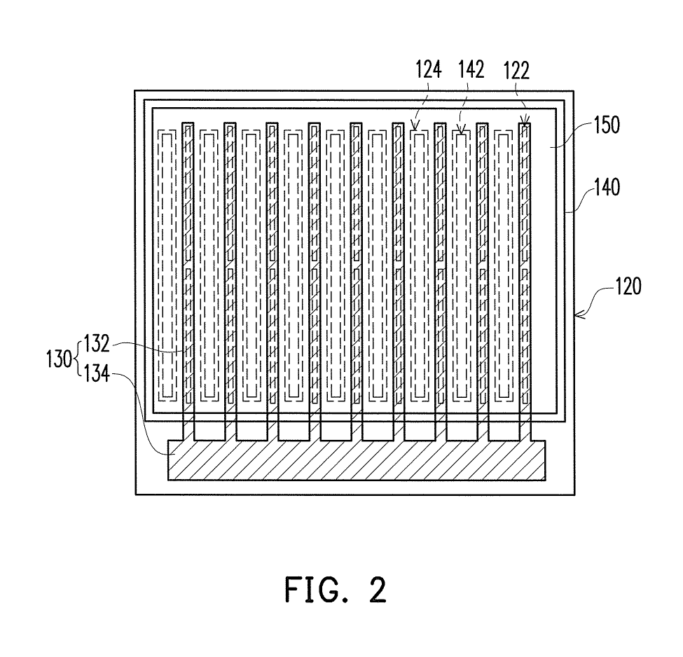

FIG. 1 is a schematic structural view of a solar cell according to an embodiment of the invention. FIG. 2 is a schematic top view of the solar cell depicted in FIG. 1. In order to represent the elements clearly, a portion of the films depicted in FIG. 2 is represented transparently.

As shown in FIGS. 1 and 2, a solar cell 100 of the present embodiment is formed on a semiconductor substrate 110. The semiconductor substrate 110 is, for example, a negative type (n-type) lightly doped semiconductor substrate, for instance a crystal silicon substrate doped with an n-type dopant such as phosphorous or arsenic dopants. The semiconductor substrate also can be a positive type (p-type) lightly doped semiconductor substrate or an intrinsic type (i-type) semiconductor substrate. The semiconductor substrate 110 has a first surface 110a and a second surface 110b opposite to the first surface 110a. A plurality of first doping regions 112 and a plurality of second doping regions 114 are formed in the first surface 110a of the semiconductor substrate 110. The first doping regions 112 are, for example, n-type heavily doped regions, for instance doping regions having an n-type dopant such as phosphorous or arsenic dopants. The second doping regions 114 are, for example, positive type (p-type) heavily doped regions, for instance doping regions having a p-type dopant such as boron, aluminum, gallium, or indium dopants.

A first passivation layer 120 covers the first surface 110a of the semiconductor substrate 110. The first passivation layer 120 has a plurality of first openings 122 and a plurality of second openings 124. The first openings 122 correspond to the first doping regions 122, and the second openings 124 correspond to the second doping regions 114. The first openings 122 and the second openings 124 are, for example, a plurality of grooves, circular openings, rectangular openings, or openings having other shapes or patterns. The first electrode 130 is disposed on the first passivation layer 120, and the first electrode 130 fills the first openings 122 so as to connect to the first doping regions 122. In the present embodiment, the first electrode 130 has a comb-like shape. Moreover, the first electrode 130 has a plurality of branches 132 parallel to each other, and a connecting portion 134 connected to the branches 132. The first doping regions 112 are disposed along the branches 132, for example, and the aforementioned groove-like first openings 122 are disposed below the branches 132, for instance, so the branches 132 connect down to the first doping regions 122 through the first openings 122. In addition, a material of the first electrode 130 may include silver, aluminum, gold, copper, molybdenum, titanium, and alloys and stacked layers thereof, or other suitable conductive materials.

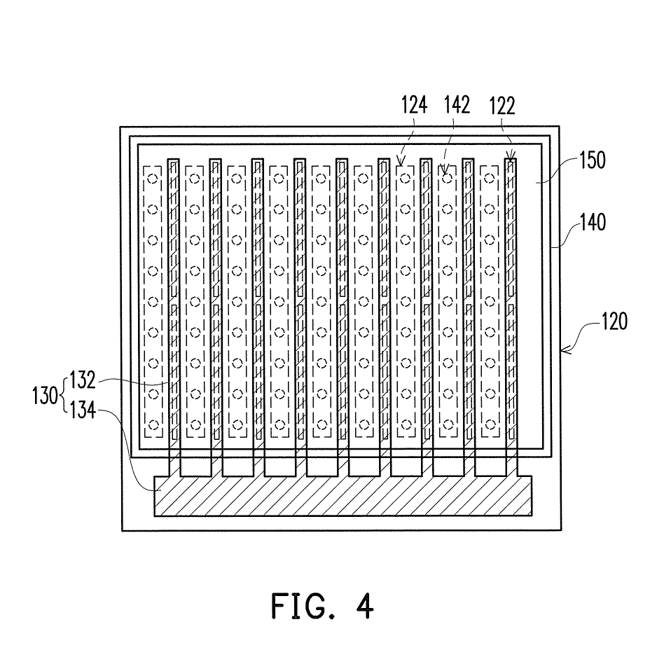

A second passivation layer 140 is disposed on the first passivation layer 120, so as to cover the branches 132 of the first electrode 130, expose the connecting portion 134 of the first electrode 130, and connect to an external circuit. Moreover, the second passivation layer 140 has a plurality of third openings 142 connected to the corresponding second openings 124. The third openings 142 may have the same shape as the second openings. The third openings 142 may all be strip-like grooves as shown in FIG. 2, or all be circular or rectangular shaped openings. The third openings 142 and the second openings 124 may also have different shapes. For example, the second openings are strip-like grooves, and the third openings 142 are dot-like circular openings, as shown in FIG. 4. However, the foregoing description is merely an illustrative example not meant to limit the shapes and arrangements. When the first openings 122 and the second openings 124 are grooves, a large area may be provided for the first doping regions 122 and the second doping regions 114, thereby obtaining a large current transmitting capability. Moreover, when the third openings 142 are circular openings, the subsequently formed second electrode 150 may easily contact the second doping regions 114 underneath, and thus avoiding a poor step coverage and affecting the processing yield.

The second electrode 150 covers the second passivation layer 140 and fills the third openings 142 and the second openings 124, so as to connect to the second doping regions 114. In the present embodiment, the second doping regions 114 are disposed between two adjacent first doping regions 112 below the branches 132. Moreover, the second electrode 150 has a sheet-like shape and covers the branches 132 of the first electrode 130. A material of the second electrode 150 may include a material of high reflectivity such as aluminum or silver. Due to the sheet-like second electrode 150, the semiconductor substrate 110 of the solar cell 100 is fully covered and has a high reflectivity. Accordingly, an incident light is conducive to being reflected at the second electrode 150, and therefore the solar cell 100 can again perform absorption conversion and enhance the light utilization rate of the solar cell 100. Moreover, with the comb-like first electrode 130 and the sheet-like second electrode 150 in combination with the corresponding first doping regions 112 and the second doping regions 114, the space in the semiconductor substrate can be fully utilized to provide a high photoelectric conversion efficiency.

In another perspective, the second surface 110b of the semiconductor substrate 110 serves as an incident surface. In order to increase the amount of incident light and the uniformity thereof, the second surface 110b may be processed into a texturized surface. Moreover, in the present embodiment, a multilayered anti-reflection coating layer or an anti-reflection coating layer 160 may be disposed on the second surface 100b of the semiconductor substrate 110, so as to increase the amount of incident light of the solar cell 100.

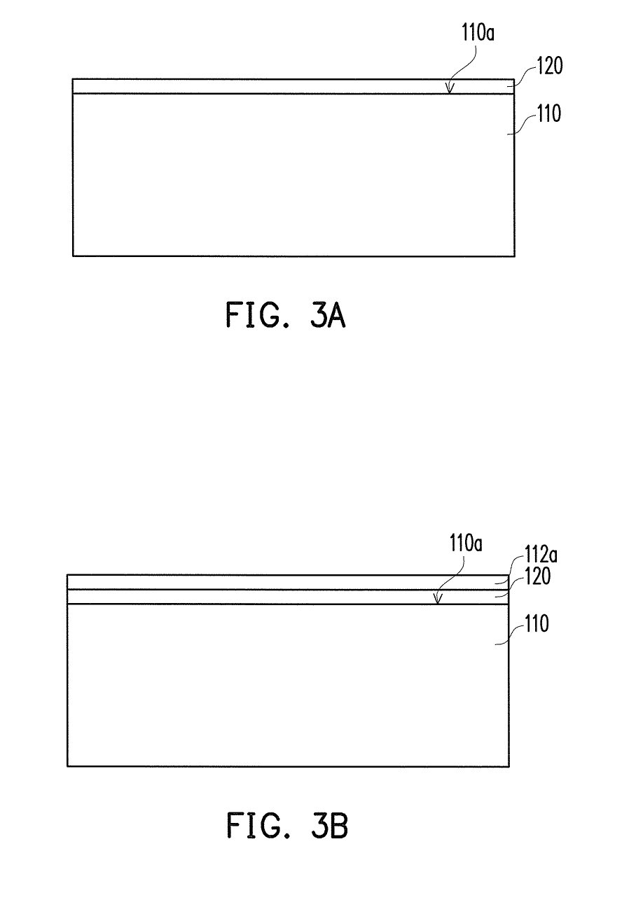

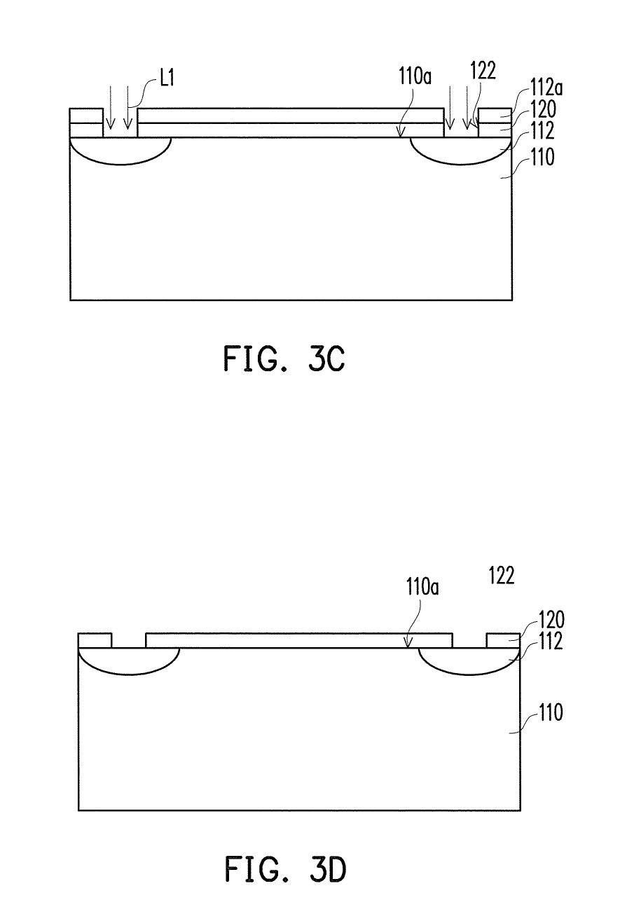

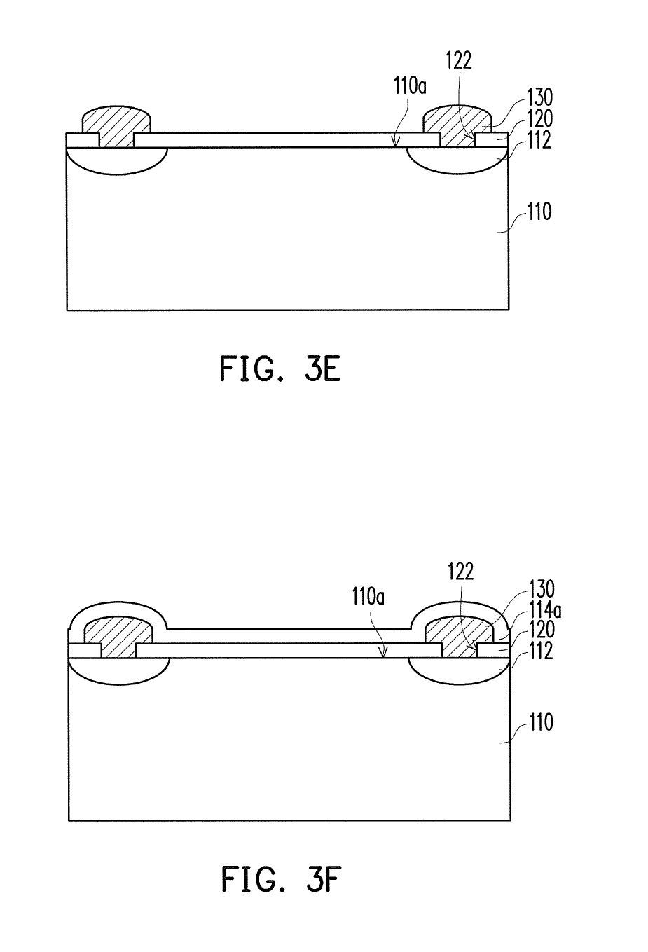

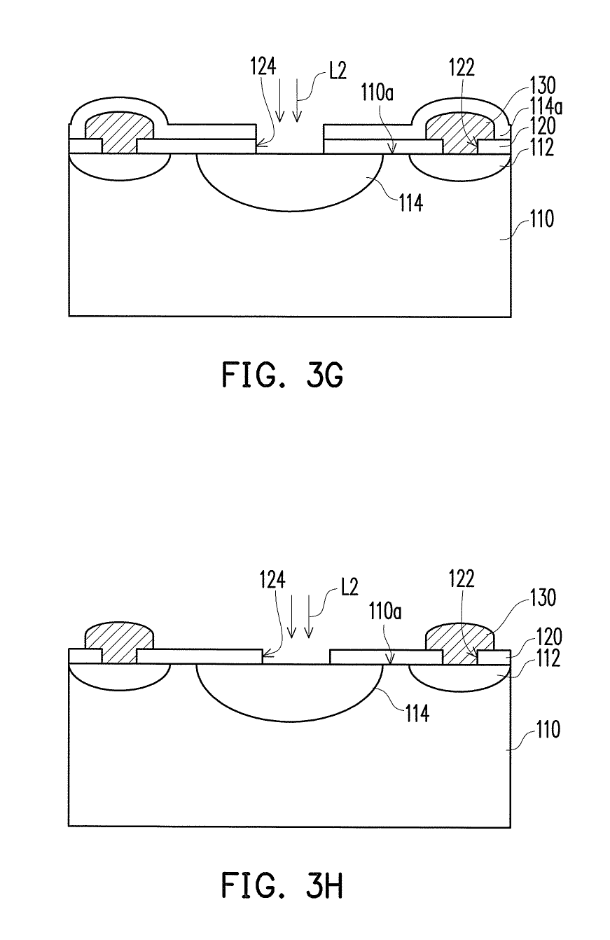

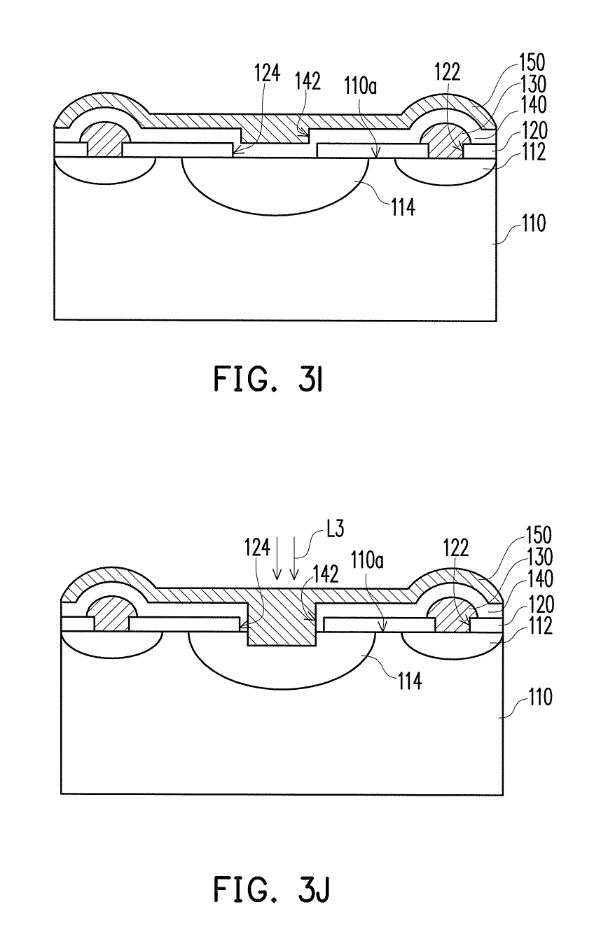

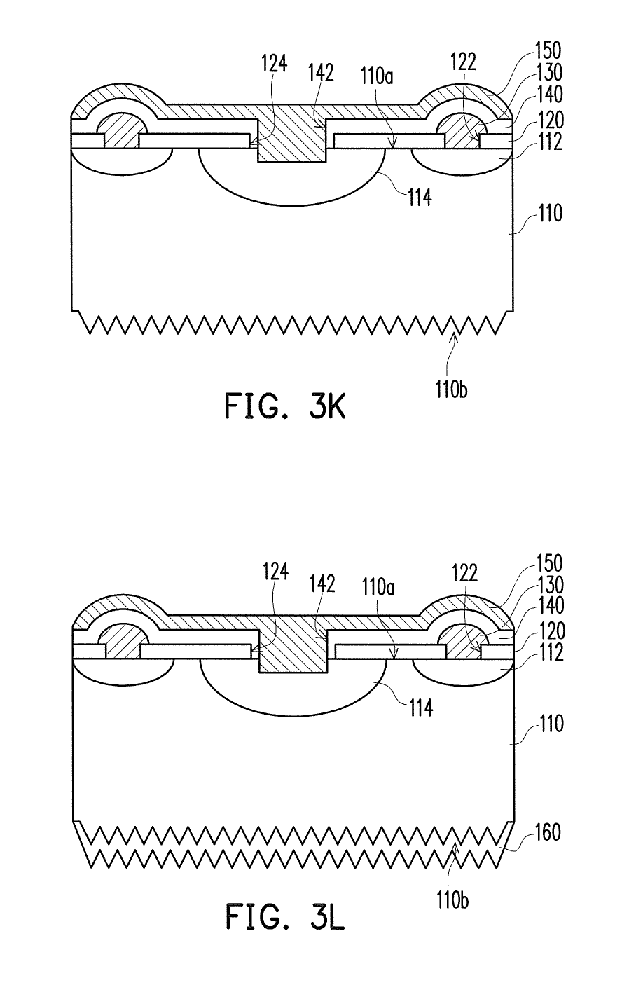

FIGS. 3A-3L illustrate the steps of a manufacturing method of the afore-described solar cell.

First, as shown in FIG. 3A, a semiconductor substrate 110 is provided, and the first passivation layer 120 is formed on the first surface 110a of the semiconductor substrate 110.

Thereafter, as shown in FIGS. 3B-3D, a first laser doping process is performed to form a plurality of first openings 122 in the first passivation layer 120, and forming a plurality of first doping regions 112 in the semiconductor substrate 110 corresponding to the first openings 122. More specifically, as shown in FIG. 3B, the first laser doping process first forms a first doping material layer 112a on the first passivation layer 120. The first doping material layer 112a has a first (e.g. n-type) dopant therein, for example an n-type dopant such as phosphorous or arsenic dopants. Thereafter, as shown in FIG. 3B, a laser beam L1 is provided on a specific location of the first doping material layer 112a and the first passivation layer 120, to form the first openings 122 and diffusing the first dopant in the first doping material layer 122 into the semiconductor substrate 110, so as to form the first doping regions 112. Since the first openings 122 and the first doping regions 112 are formed by the same laser doping process, the first openings 122 and the first doping regions 112 have the same pattern. For example, the first openings 122 include a plurality of grooves, whereas the first doping regions 112 include a plurality of strip-like patterns corresponding to the grooves. Thereafter, as shown in FIG. 3D, the first doping material layer 112a is removed.

Next, as shown in FIG. 3E, a first electrode 130 is formed on the first passivation layer 120. The first electrode 130 has a comb-like shape and a plurality of branches 132 parallel to each other. The branches 132 of the first electrode fill the first openings 122 so as to connect to the first doping regions 112 below. Naturally, the fabricated first openings 122 and the first doping regions 112 may also be located below the connecting portion 134 of the first electrode 130. In addition, a method of forming the comb-like first electrode 130 may be a screen printing process, an electroplating process or an electroless plating process, for example. Moreover, after fabricating the first electrode 130, an annealing process may be performed to increase a contact area of the first electrode and the first doping regions through heating, and to effectively lower the contact resistance.

Thereafter, as shown in FIGS. 3F-3H, a second laser doping process is performed to form a plurality of second openings 124 in the first passivation layer 120, and forming a plurality of second doping regions 114 in the semiconductor substrate 110 corresponding to the second openings 114. More specifically, as shown in FIG. 3F, the second laser doping process first forms a second doping material layer 114a on the first passivation layer 120. The second doping material layer 114a has a second (e.g. p-type) dopant therein, for example a p-type dopant such as boron, aluminum, gallium, or indium dopants. Thereafter, as shown in FIG. 3G, a laser beam L2 is provided on the second doping material layer 114a and the first passivation layer 120, to form the second openings 124 and diffusing the second dopant in the second doping material layer 114a into the semiconductor substrate 110, so as to final the second doping regions 114. Since the second openings 124 and the second doping regions 114 are formed by the same laser doping process, the second openings 124 and the second doping regions 114 have the same pattern. For example, the second openings 124 include a plurality of grooves, circular openings, or rectangular openings, whereas the second doping regions 114 include a plurality of strip-like patterns corresponding to the grooves. Thereafter, as shown in FIG. 3H, the second doping material layer 114a is removed.

Next, as shown in FIG. 3I, the second passivation layer 140 is formed on the first passivation layer 120, so as to cover the second passivation layer 140 on the branches 132 of the first electrode 130, and to cover the second electrode 150 on the second passivation layer 140 thereafter. As shown in FIG. 3J, a laser annealing process for melting aluminum 150 and passivation layer 142 is performed to provide a laser beam L3 on the second electrode 150 and the second passivation layer 140, so as to form a plurality of third openings 142 in the second passivation layer 140, in which the third openings 142 correspond to the second doping regions 114. Moreover, the second electrode 150 fills the third openings 142 so as to contact and electrically connect to the second doping regions 114. The third openings 142 include, for example, a plurality of grooves, dot-like circular openings, and rectangular openings Up to here, the fabrication of solar cell 100 is substantially completed.

Furthermore, as described earlier, in order increase the amount of incident light and the uniformity thereof, the present embodiment may choose to perform a texturing process similar to the second surface 110b of the semiconductor substrate 110 depicted in FIG. 3K. Moreover, a multilayer anti-reflection coating layer or an anti-reflection coating layer 160 may be selectively formed on the second surface 110b as depicted in FIG. 3L, so as to increase the amount of incident light and the photoelectric conversion efficiency.

In addition, the steps of FIGS. 3K and 3L may be placed between the steps of FIGS. 3A-3J. For example, in the present embodiment, the steps of FIGS. 3K and 3L may be performed after the second electrode 150 is formed in the step of FIG. 3J. Alternatively, the steps of FIGS. 3A-3J may be performed after the texturing process of the second surface 110b of the semiconductor substrate 110 as depicted in FIG. 3K, and the selective formation of the anti-reflection coating layer 160 on the second surface 110b.

In view of the foregoing, the solar cell according to an embodiment of the invention adopts the comb-like first electrode and the sheet-like second electrode in combination with the corresponding first doping regions and the second doping regions, so as to fully utilize the space in the semiconductor substrate to provide a high photoelectric conversion efficiency. Moreover, since the second electrode has a sheet-like shape and may be fabricated from materials having a high reflectivity, the light utilization rate of the solar cell can be enhanced. From another perspective, since laser doping processes are adopted in an embodiment to form doping regions of the solar cell, the location of the doping regions can be accurately defined. Moreover, contact materials may be directly filled in the laser formed openings, and therefore no step coverage issue arises as in conventional metal contacts. In other words, according to embodiments of the invention, the manufacturing process of the solar cell is simplified and the processing yield is improved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A manufacturing method of a solar cell, comprising:
providing a semiconductor substrate having a first surface and a second surface opposite to the first surface;
forming a first passivation layer on the first surface of the semiconductor substrate;
performing a first laser doping process to form a plurality of first openings in the first passivation layer, and to form a plurality of first doping regions in the semiconductor substrate corresponding to the first openings;
forming a first electrode on a portion of the first passivation layer, the first electrode having a plurality of branches parallel to each other, and the first electrode filling the first openings to connect the first doping regions;
performing a second laser doping process to form a plurality of grooves in the first passivation layer, and to form a plurality of second doping regions in the semiconductor substrate corresponding to the grooves, and wherein the grooves and the branches are alternately arranged;
forming a second passivation layer on the first passivation layer, the second passivation layer covering the branches of the first electrode;
forming a second electrode on the second passivation layer, the second electrode covering the branches of the first electrode; and
performing a laser annealing process to form a plurality of third openings in the second passivation layer, the third openings corresponding to the second doping regions, each of the grooves being corresponding to a plurality of the third openings, the second electrode filled in the third openings to connect the second doping regions.

2. The manufacturing method as claimed in claim 1, wherein the first laser doping process comprises:
forming a first doping material layer on the first passivation layer, the first doping material layer having a first dopant therein;
providing a laser beam on the first doping material layer and the first passivation layer to form the first openings and diffusing the first dopant from the first doping material layer into the semiconductor substrate, so as to form the first doping regions; and
removing the first doping material layer.

3. The manufacturing method as claimed in claim 1, wherein the second laser doping process comprises:
forming a second doping material layer on the first passivation layer, the second doping material layer having a second dopant therein;
providing a laser beam on the second doping material layer and the first passivation layer to form the grooves and diffusing the second dopant in the second doping material layer into the semiconductor substrate, so as to form the second doping regions; and
removing the second doping material layer.

4. The manufacturing method as claimed in claim 1, wherein a method of forming the first electrode comprises a screen printing process.

5. The manufacturing method as claimed in claim 4, further comprising performing an annealing process after forming the first electrode.

6. The manufacturing method as claimed in claim 1, further comprising performing a texturing process on the second surface of the semiconductor substrate.

7. The manufacturing method as claimed in claim 1, further comprising forming an anti-reflection coating layer on the second surface of the semiconductor substrate.
